(19) United States
(12) Patent Application Publication
(10) Pub. No.: US 2009/0269923 A1
(43) Pub. Date: Oct. 29, 2009

(54) ADHESION AND ELECTROMIGRATION IMPROVEMENT BETWEEN DIELECTRIC AND CONDUCTIVE LAYERS

(76) Inventors: Sang M. Lee, Cupertino, CA (US); Yong-Won Lee, Santa Clara, CA (US); Meiyee Shek, Palo Alto, CA (US); Li-Qun Xia, Cupertino, CA (US); Derek R. Witty, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/109,533

(22) Filed: Apr. 25, 2008

(51) Int. Cl. H01L 21/321

(52) U.S. Cl. 438/655; 257/E21.296; 257/E21.302; 257/E21.579; 257/E21.584

(57) ABSTRACT

A method and apparatus for processing a substrate is provided. The method of processing a substrate includes providing a substrate comprising a conductive material, performing a pre-treatment process on the conductive material, flowing a silicon based compound on the conductive material to form a silicide layer, performing a post treatment process on the silicide layer, and depositing a barrier dielectric layer on the substrate.

### BACKGROUND OF THE INVENTION

1. Field of the Invention

Embodiments of the present invention generally relate to the fabrication of integrated circuits. More particularly, embodiments of the present invention relate to a method and apparatus for processing a substrate that includes depositing metal nitrosilicide between a conductive material and a barrier dielectric material to improve adhesion and electromigration between the conductive material and the barrier dielectric material.

2. Description of the Related Art

Integrated circuits have evolved into complex devices that can include millions of components (e.g., transistors, capacitors and resistors) on a single chip. The evolution of chip designs continually requires faster circuitry and greater circuit densities. The demand for greater circuit densities necessitates a reduction in the dimensions of the integrated circuit components.

As the dimensions of the integrated circuit components are reduced (e.g., sub-micron dimensions), the materials used to fabricate such components contribute to the electrical performance of such components. For example, low resistivity metal interconnects (e.g., aluminum and copper) provide conductive paths between the components on integrated circuits.

One method for forming vertical and horizontal interconnects is by forming a damascene or dual damascene structure. In a damascene structure, one or more dielectric materials, such as the low k dielectric materials, are deposited and pattern etched to form vertical interconnects, i.e. vias, and horizontal interconnects, i.e., lines. Conductive materials, such as copper containing materials, and other materials, such as barrier layer materials used to prevent diffusion of copper containing materials into the surrounding low k dielectric, are then inlaid into the etched pattern. Excess copper containing materials and excess barrier layer material external to the etched pattern, such as on the field of the substrate between the lines, are then removed to form a planarized surface. A dielectric layer, such as an insulative layer or barrier layer is formed over the copper feature for subsequent processing, such as forming a second layer of vertical and horizontal interconnects.

However, it has been observed that certain dielectric layers having superior electrical properties exhibit poor adhesion to copper features. This poor adhesion between the dielectric layers and the copper features leads to high capacitive coupling between adjacent metal interconnects causing cross-talk, resistance-capacitance (RC) delay, and electromigration failure which degrades the overall performance of the integrated circuit.

Therefore, there remains a need for a process for improving interlayer adhesion and electromigration between low k dielectric layers overlying copper features.

### SUMMARY OF THE INVENTION

The present invention generally provides a method of processing a substrate. In one embodiment, the method includes providing a substrate comprising a conductive material, performing a pre-treatment process on the conductive material, flowing a silicon based compound on the conductive material to form a silicide layer, performing a post treatment process on the silicide layer, and depositing a barrier dielectric layer on the substrate.

In another embodiment, a method for processing a substrate includes providing a substrate comprising a conductive material, flowing a silicon based compound over the surface of the conductive material to form a silicide, treating the substrate with a nitrogen containing plasma to form a metal nitrosilicide layer, and depositing a barrier layer on the substrate.

In yet another embodiment, a method for processing a substrate includes providing a substrate comprising a conductive material, performing a nitrogen pre-treatment process by a NH₃ gas on the conductive material, flowing a silane gas over the surface of the conductive material to form a silicide, treating the silicide by a NH₃ gas containing plasma to form a metal nitrosilicide, and depositing a barrier dielectric layer comprising silicon carbide on the metal nitrosilicide.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1D are cross-sectional views showing one embodiment of a dual damascene deposition sequence according to one embodiment of the invention;

FIG. 2 is a process flow diagram illustrating a method for depositing a metal nitrosilicide layer over a conductive layer;

FIG. 3A-3D are cross-sectional views showing metal nitrosilicide layer formed on a conductive layer; and

FIG. 4 is a cross sectional schematic diagram of an exemplary processing chamber that may be used for practicing embodiments of the invention.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present invention generally provide a method of processing a substrate that includes performing a sequence of silane flow and plasma treatment process prior to depositing a barrier dielectric layer on a conductive material. In certain embodiments, the method include performing a pre-treatment process, a silicide formation process and post nitrogen treatment process on a conductive layer to form a metal nitrosilicide prior to depositing a barrier dielectric layer. The pre-nitrogen treatment assists removal of surface oxide and contaminants from the substrate surface. A silicide of the conductive material is formed followed by the pre-treatment process. The post nitrogen plasma treatment process is performed on the silicide to form a metal nitrosilicide prior to deposition of the barrier dielectric layer. Optionally, the nitrosilicide may serve as the interface layer. In certain embodiments, the silicide material is copper silicide and the metal nitrosilicide is CuSiN. In certain embodiments, the conductive material is copper and the barrier dielectric material is silicon carbide.

While the following description details the use of the sequence of the plasma process to improve interface adhesion and electromigration between a conductive material and a barrier dielectric material for a dual damascene structure, the invention should not be construed or limited to the illustrated examples, as the invention contemplates that other structures, formation processes, and straight deposition processes may be performed using the adhesion and electromigration aspects described herein.

The following deposition processes are described with use of the 300 mm Producer® dual deposition station processing chamber, and should be interpreted accordingly. For example, flow rates are total flow rates and should be divided by two to describe the process flow rates at each deposition station in the chamber. Additionally, it should be noted that the respective parameters may be modified to perform the plasma processes in various chambers and for different substrate sizes, such as for 300 mm substrates. Further, while the following process is described for copper, silicon carbide and copper nitrosilicide, the invention contemplates this process may be used to improve the adhesion and electromigration between other conductive and barrier dielectric materials.

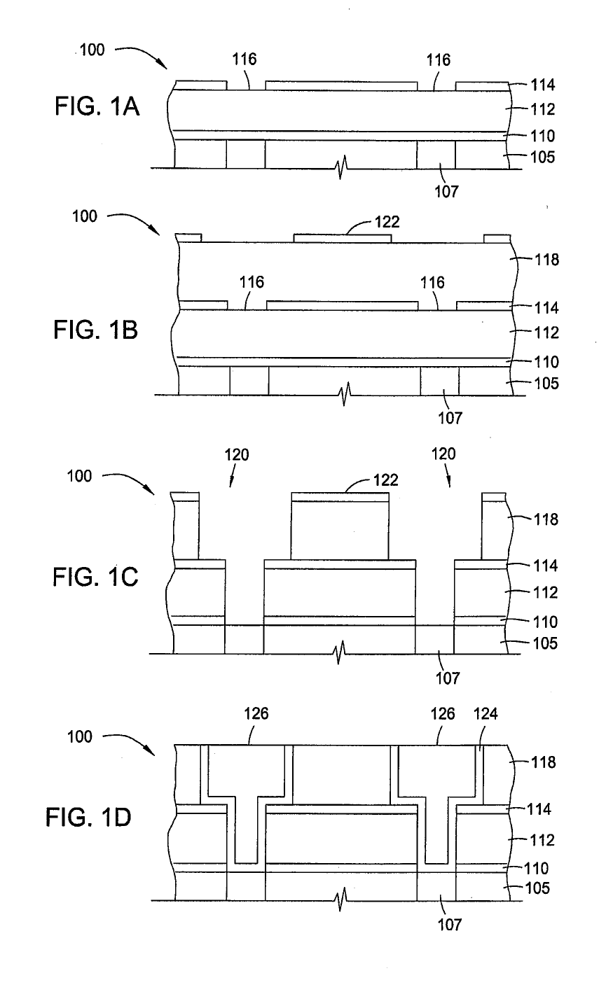

FIG. 1 depicts a damascene formed on a substrate 100 having metal features 107 formed within an insulating material 105. A first silicon carbide barrier layer 110 is generally deposited on the insulating material 105 to eliminate inter-level diffusion between insulating material 105 disposed on the substrate 100 and subsequently deposited material. In one embodiment, silicon carbide barrier layers may have dielectric constants of about 5 or less, such as less than about 4.

The silicon carbide material of the first silicon carbide barrier layer 110 may be doped with nitrogen and/or oxygen. An optional capping layer of nitrogen free silicon carbide or silicon oxide (not shown) may be deposited on the barrier layer 110. The nitrogen free silicon carbide or silicon oxide capping layer may be deposited in situ by adjusting the composition of the processing gas. For example, a capping layer of nitrogen free silicon carbide may be deposited in situ on the first silicon carbide barrier layer 110 by minimizing or eliminating the nitrogen source gas. Alternatively, and not shown, an initiation layer may be deposited on the first silicon carbide barrier layer 110. Initiation layers are more fully described in U.S. Pat. No. 7,030,041, entitled ADHESION IMPROVEMENT FOR LOW K DIELECTRICS, which is incorporated herein by reference.

The first dielectric layer 112 is deposited on the silicon carbide barrier layer 110 to a thickness of about 5,00 to about 15,000 Å, depending on the size of the structure to be fabricated, by oxidizing an organosilicon compound, which may include trimethylsilane and/or octamethylcyclotetrasiloxane. The first dielectric layer 112 may then be post-treated with a plasma or e-beam process. Optionally, a silicon oxide cap layer (not shown) may be deposited in situ on the first dielectric layer 112 by increasing the oxygen concentration in the silicon oxycarbide deposition process to remove carbon from the deposited material. The first dielectric layer may also comprise other low k dielectric material such as a low polymer material including paralyne or a low k spin-on glass such as un-doped silicon glass (USG) or fluorine-doped silicon glass (FSG). The first dielectric layer may then be treated by a plasma process.

An optional low-k (or second barrier layer) 114, for example a silicon carbide, which may be doped with nitrogen or oxygen, is then deposited on the first dielectric layer 112. The low-k etch stop 114 may be deposited on the first dielectric layer 112 to a thickness of about 100 Å to about 1,000 Å. The optional low k etch stop 114 may be plasma treated as described herein for the silicon carbide materials or silicon oxycarbide materials. The low-k etch stop 114 is then pattern etched to define the openings of the contacts/vias 116 and to expose the first dielectric layer 112 in the areas where the contacts/vias 116 are to be formed. In one embodiment, the low-k etch stop 114 is pattern etched using conventional photolithography and etch processes using fluorine, carbon, and oxygen ions. While not shown, a nitrogen-free silicon carbide or silicon oxide cap layer between about 100 Å to about 500 Å may optionally be deposited on the low-k etch stop 114 prior to depositing further materials.

Referring to FIG. 1B, a second dielectric layer 118 of an oxidized organosilane or organosiloxane is deposited over the optional patterned etch stop 114 and the first dielectric layer 112 after the resist material has been removed. The second dielectric layer 118 may comprise silicon oxycarbide from an oxidized organosilane or organosiloxane by the process described herein, such as trimethylsilane, is deposited to a thickness of about 5,000 to about 15,000 Å. The second dielectric layer 118 may then be plasma or e-beam treated and/or have a silicon oxide cap material disposed thereon.

A resist material 122 is deposited on the second dielectric layer 118 (or cap layer) and patterned using conventional photolithography processes or other suitable process to define the interconnect lines 120, as shown in FIG. 1B. Optionally, an ARC layer and a etch mask layer, such as a hardmask layer, (not shown) may be optionally between the resist material 122 and the second dielectric layer 118 to facilitate transferring patterns and features to the substrate 100. The resist material 122 comprises a material conventionally known in the art, for example a high activation energy resist material, such as UV-5, commercially available from Shipley Company Inc., of Marlborough, Mass. The interconnects and contacts/vias are then etched using reactive ion etching or other anisotropic etching techniques to define the metallization structure (i.e., the interconnect and contact/via) as shown in FIG. 1C. Any resist material or other material used to pattern the etch stop 114 or the second dielectric layer 118 is removed using an oxygen strip or other suitable process.

The metallization structure is then formed with a conductive material such as aluminum, copper, tungsten or combinations thereof. Presently, the trend is to use copper to form the smaller features due to the low resistivity of copper (1.7 mΩ-cm compared to 3.1 mΩ-cm for aluminum). In one embodiment, a suitable metal barrier layer 124, such as tantalum nitride, is first deposited conformally in the metallization pattern to prevent copper migration into the surrounding silicon and/or dielectric material. Thereafter, copper is deposited using techniques such as chemical vapor deposition, physical vapor deposition, electroplating, or combinations thereof to form the conductive structure. Once the structure has been filled with copper or other conductive metal, the surface is planarized using chemical mechanical polishing and exposing the surface of the conductive metal feature 126, as shown in FIG. 1D.

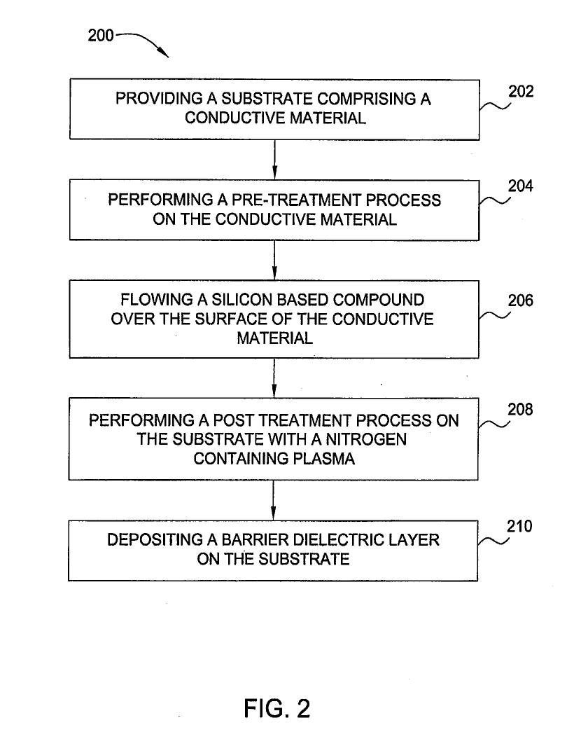

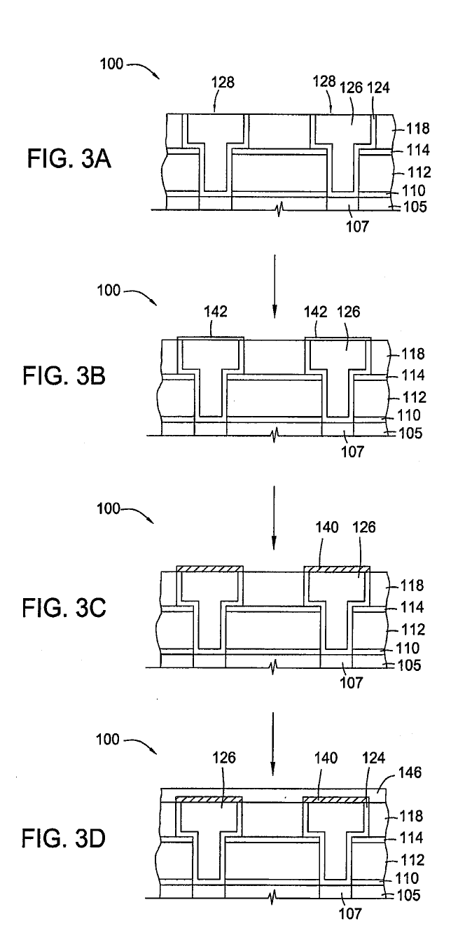

FIG. 2 is a process flow diagram illustrating a method 200 according to one embodiment of the invention for forming a thin interface layer on a substrate 100. The method starts at step 202 by providing a substrate 100 comprising a conductive material 126 having an exposed surface 128 disposed on the substrate 100, as shown in FIG. 3A. The conductive materials 126 may be fabricated from Sn, Ni, Cu, Au, Al, combinations thereof, and the like. Conductive materials 126 may also include a corrosion resistant metal such as Sn, Ni, or Au coated over an active metal such as Cu, Zn, Al, and the like. In certain embodiments, the substrate 100 further comprises a silicon containing layer, a first dielectric layer 112 and a second dielectric layer 118, circumscribing the conductive material 126. In one embodiment, the first dielectric layer 112 and the second dielectric layer 118 formed on the substrate 100 may be a low-k dielectric layer having a dielectric constant lower than 4.0, such as silicon oxycarbide, among others. In certain embodiments, a silicon oxycarbon layer, such as BLACK DIAMOND®, commercialized available from Applied Material Inc., Santa Clara, Calif., may be utilized to form the first and the second dielectric barrier layer 112, 118. In certain embodiments, the conductive material 126 and the first 112 and the second dielectric layer 118 formed on the substrate 100 comprise a damascene structure.

In step 204, a pre-treatment process having nitrogen plasma is performed to treat the upper surface of the second dielectric layer 118 and the exposed surface 128 of the conductive material 126. The pre-treatment process may assist removing metal oxide, native oxide, particles, or contaminants from the substrate surface. In one embodiment, the gases utilized to treat the substrate 100 include N₂, N₂O, NH₃, NO₂, and the like. In a certain embodiment depicted herein, the nitrogen containing gas used to pre-treat the second dielectric layer 118 and the exposed surface 128 of the conductive material 126 is ammonia (NH₃) or nitrogen gas (N₂).

In one embodiment, the pre-treatment process at step 204 is performed by generating a plasma in a gas mixture supplied to the processing chamber. The plasma may be generated by applying a power density ranging between about 0.03 W/cm² and about 3.2 W/cm², which is a RF power level of between about 10 W and about 1,000 W for a 300 mm substrate, for example, between about 100 W and about 400 W at a high frequency such as between 13 MHz and 14 MHz, for example, 13.56 MHz. The plasma may be generated by applying a power density ranging between about 0.01 W/cm² and about 1.4 W/cm², which is a RF power level of between about 10 W and about 1,000 W for a 300 mm substrate, for example, between about 100 W and about 400 W at a high frequency such as between 13 MHz and 14 MHz, for example, 13.56 MHz. Alternatively, the plasma may be generated by a dual-frequency RF power source as described herein. Alternatively, all plasma generation may be performed remotely, with the generated radicals introduced into the processing chamber for plasma treatment of a deposited material or deposition of a material layer.

In step 206, a silicon based compound is flowed over the treated surface of the conductive material 126. The silicon based compound reacts with the conductive material 126 to form a silicide 142 over the conductive material 126, as shown in FIG. 3B. The silicon atoms from the silicon based compound are adhered and absorbed on the surface of the conductive material 126 on the substrate 100, thereby forming metal silicide layer 142 on the substrate 100. In embodiments wherein the conductive material 126 on the substrate 100 is a copper layer, the silicon atoms are adhered and absorbed on the copper surface, thereby forming copper silicide layer on the copper conductive layer surface 126.

The silicon based compound supplied to the pre-treated surface of the conductive material 126 may be performed by a thermal process, e.g., without in presence of a plasma. In this particular embodiment, the silicide deposition may be formed mainly on the conductive material surface. The thermal energy assists the silicon atoms from the silicon based compound to mainly be absorbed on the copper atoms of the conductive material 126, forming the silicide layer 142 on the conductive material surface. Alternatively, in the embodiment wherein the silicon based compound supplied to the processing chamber is performed by a plasma process, the silicide deposition 142 may be formed all over the surface of the substrate 100, such as on both the surface of the conductive material 126 and dielectric material 118. In the embodiment wherein the conductive material 126 is a copper layer, the silicide layer 142 formed on the substrate 100 is a copper silicide (CuSi) layer.

The silicon based compound may comprise a carbon-free silicon compound including silane, disilane, and derivatives thereof. The silicon based compound may also comprise a carbon-containing silicon compound including organosilicon compounds described herein, for example, trimethylsilane (TMS) and/or dimethylphenyl silane (DMPS). The silicon based compound may react with the exposed conductive material by thermally and/or alternatively, plasma enhanced process. Dopants, such as oxygen and nitrogen may used with the silicon based compound as describe herein. Additionally, an inert gas, such as a noble gas including helium and argon, may be used during the silicide process, and may be used as a carrier gas for the thermal process or as an additional plasma species for the plasma enhanced silicide formation process. The silicon based compound may further include a dopant, such as the reducing compound described herein, to form a nitrosilicide. In such an embodiment, the reducing compound may be delivered as described herein.

In one embodiment, the silicon based compound is provided to the processing chamber at a flow rate between about 40 sccm and about 5000 sccm, for example, between about 1000 sccm and about 2000 sccm. Optionally, an inert gas, such as helium, argon or nitrogen, may also be supplied to a processing chamber at a flow rate between about 100 sccm and about 20,000 sccm, for example, between about 15,000 sccm and about 19,000 sccm. The process chamber pressure may be maintained between about 1 Torr and about 8 Torr, for example, between about 3 Torr and about 5 Torr. The heater temperature may be maintained between about 100° C. and about 500° C., for example, between about 250° C. and about 450° C., such as less than 300° C. A spacing between a gas distributor, or showerhead of between about 200 mils and about 1000 mils, for example between 300 mils and 500 mils from the substrate surface. The silicide layer formation process may be performed between about 1 second and about 20 seconds, for example, between about 2 second and about 8 seconds.

A specific example of the silicide process includes providing silane to a processing chamber at a flow rate of about 125 sccm, providing nitrogen to a processing chamber at a flow rate of about 18000 sccm, maintaining a chamber pressure at about 4.2 Torr, maintaining a heater temperature of about 350° C., providing a spacing between a gas distributor, or showerhead of about 350 mils from the substrate, for about 4 seconds.

In step 208, a post treatment process is performed on the silicide layer 142, forming a metal nitrosilicide layer 140 on the substrate 100, as shown in FIG. 3C. In one embodiment, the silicide 142 may then be treated with a nitrogen containing plasma to form the metal nitrosilicide 140. In one embodiment, the nitrogen containing plasma may be performed by supplying a nitrogen containing gas to the silicide layer 142 in presence of plasma to treat the silicide 142, incorporating nitrogen atoms to the surface of the silicide layer 142, thereby converting the silicide layer 142 into a nitrosilicide layer 140. Suitable examples of the nitrogen containing gas include N₂, N₂O, NH₃, NO₂, and the like. In a certain embodiment depicted herein, the nitrogen containing gas used to post treatment the silicide layer 142 is ammonia (NH₃).

In one embodiment, the nitrosilicide layer 140 acts as an interface layer that promotes adhesion between the conductive material 126 and the subsequent to-be-deposited film. The nitrosilicide layer 140 serves as an adhesion enhancement layer that bridges the copper atoms from the conductive material 126 and the silicon and nitrogen atoms from the silicide formation process at step 206, thereby forming strong bonding at the interface. The strong bonding of the nitrosilicide layer 140 to the conductive material 126 enhances the adhesion between the conductive material 126 and the subsequently to-be deposited barrier dielectric layer 146, thereby efficiently improving integration of the interconnection structure and device electromigration. Additionally, the nitrosilicide layer also serves as a barrier layer that prevents the underlying conductive layer diffusing to the adjacent dielectric layer, thereby improving electromigration performance and overall device electrical performance.

The silicide formation process at step 206 and post plasma nitridation treatment at step 208 are controlled in a manner that promotes interfacial adhesion and device electromigration performance without adversely impacting film resistivity. The metal nitrosilicide layer 140 is formed to a desired thickness sufficient to serve as an effective metal diffusion barrier while maintaining a minimum metal resistance. In one embodiment, the thickness of the metal nitrosilicide layer is less than about 50 Å, such as between about 30 Å to about 40 Å. Silicon atoms from the metal silicide formation process and nitrogen atoms from the plasma nitridation process react with copper atoms from the conductive material, forming the copper nitrosilicide layer, such as CuSiN, on the substrate. Silicon atoms and nitrogen atoms provided to the processing chamber to react with the copper atoms is controlled at a desired ratio and amount to form the nitrosilicide layer 140 under a desired film property. It is believed that excess amount of silicon atoms from the silicide formation process may not react with the nitrogen atoms, resulting in excess silicon atoms remaining on the metal conductive surface. During the subsequent annealing or thermal treatment processes, excess silicon atoms may diffuse further down to the metal conductive material 126, thereby increasing metal sheet resistance and adversely impacting the device electrical properties. In contrast, insufficiently amount of silicon atoms may result in excess nitrogen atoms left on the substrate 100, thereby forming unwanted copper nitride cluster on the substrate 100. The unwanted copper nitride cluster may become a source of particle defect, contaminating and polluting the films formed on the substrate. Accordingly, a well process control of silicide formation process at step 206 and post plasma nitridation treatment process at step 210 is necessary to obtain a metal nitrosilicide layer 140 with desired interfacial property.

In one embodiment, the process time for performing the silicide formation process at step 206 and post plasma nitridation treatment process at step 208 is controlled at between about 1:5 to about 5:1, such as about 1:3 and about 3:1. In another embodiment, the process time for performing the silicide formation process at step 206 is controlled less than about 10 seconds, such as less than about 5 seconds, and the post plasma nitridation treatment process at step 208 is controlled at less than about 30 second, such as less than 15 seconds. In yet another embodiment, the process time for performing the silicide formation process step 206 is less than the process time for performing the post plasma nitridation treatment process at step 208.

The nitrogen source for the nitrogen containing plasma may be nitrogen (N₂), NH₃, N₂O, NO₂, or combinations thereof. The plasma may further comprise an inert gas, such as helium, argon, or combinations thereof. The pressure during the plasma exposure of the substrate may be between about 1 mTorr and about 30 mTorr, such as between about 1 mTorr and about 10 mTorr. Besides N₂, other nitrogen-containing gases may be used to form the nitrogen plasma, such as H₃N hydrazines (e.g., N₂H₄ or MeN₂H₃), amines (e.g., Me₃N, Me₂NH or MeNH₂), anilines (e.g., C₅H₅NH₂), and azides (e.g., MeN₃ or Me₃SiN₃). Other noble gases that may be used in a DPN process include helium, neon, and xenon. The nitridation process proceeds at a time period from about 10 seconds to about 360 seconds, for example, from about 0 seconds to about 60 seconds, for example, about 15 seconds.

The RF power selected to perform the post treatment process is controlled substantially similar to the RF power selected to pre-treat the substrate 100 at step 204. In one embodiment, The plasma may be generated by applying a power density ranging between about 0.03 W/cm² and about 3.2 W/cm², which is a RF power level of between about 10 W and about 1,000 W for a 300 mm substrate, for example, between about 100 W and about 600 W at a high frequency such as between 13 MHz and 14 MHz, for example, 13.56 MHz. The plasma may be generated by applying a power density ranging between about 0.01 W/cm² and about 1.4 W/cm², which is a RF power level of between about 10 W and about 1,000 W for a 300 mm substrate, for example, between about 100 W and about 400 W at a high frequency such as between 13 MHz and 14 MHz, for example, 13.56 MHz. Alternatively, the plasma may be generated by a dual-frequency RF power source as described herein. Alternatively, all plasma generation may be performed remotely, with the generated radicals introduced into the processing chamber for plasma treatment of a deposited material or deposition of a material layer. In one embodiment, the nitridation process is conducted with a RF power setting at about 300 watts to about 2,700 watts and a pressure at about 1 mTorr to about 100 mTorr. A nitrogen containing gas has a flow rate from about 0.1 slm to about 15 slm. In one embodiment, the nitrogen containing gas includes a gas mixture having a nitrogen and an ammonia gas is supplied into the processing chamber. The nitrogen gas is supplied to the chamber between about 0.5 slm and about 1.5 slm, for example, about 1 slm and the ammonia gas is supplied to the chamber between about 5 slm and about 15 slm, such as about 10 slm.

The individual and total gas flows of the processing gases may vary based upon a number of processing factors, such as the size of the processing chamber, the temperature of the processing chamber, and the size of the substrate being processed. The process chamber pressure may be maintained between about 1 Torr and about 10 Torr, for example, between about 2 Torr and about 5 Torr, such as about 3.7 Torr. The heater temperature may be maintained between about 100° C. and about 500° C., for example, between about 250° C. and about 450° C., such as less than 350° C.

In step 210, a barrier dielectric layer 146 is deposited on the metal nitrosilicide 140 formed on the substrate 100. In certain embodiments, the barrier dielectric layer 146 may comprise a silicon carbide material or other suitable dielectric material. After the metal nitrosilicide 140 is formed, the barrier dielectric layer 146, such as a silicon carbide layer, may be subsequently deposited thereon. The formation of the metal nitrosilicide layer 140 and the barrier dielectric layer 146 may be performed in situ. Processes for depositing barrier dielectric layer, such as a silicon carbide, are described in U.S. Pat. No. 6,537,733, entitled METHOD OF DEPOSITING LOW DIELECTRIC CONSTANT SILICON CARBIDE LAYERS, U.S. Pat. No. 6,759,327, entitled DEPOSITING LOW K BARRIER FILMS (k<4) USING PRECURSORS WITH BULKY ORGANIC FUNCTIONAL GROUPS, and U.S. Pat. No. 6,890,850, entitled METHOD OF DEPOSITING LOWER K HARDMASK AND ETCH STOP FILMS, which are all incorporated herein by reference in their entireties to the extent not inconsistent with the claimed aspects and disclosure herein.

In one embodiment, the RF power applied to post-treat process at step 208 may be maintained and continued to the barrier dielectric layer deposition process at step 210. Alternatively, the RF power applied to post-treat process may be turned off after the post-treat process at step 208 is completed and re-applied at step 210 to perform the barrier dielectric deposition process at step 210.

It is noted that the pre-treatment process at step 204, silicide formation process at step 206, post treatment process at step 208 and the barrier dielectric layer at step 210 may be in-situ deposited in a single chamber. Alternatively, the steps may be deposited and performed in different chambers in any different arrangement.

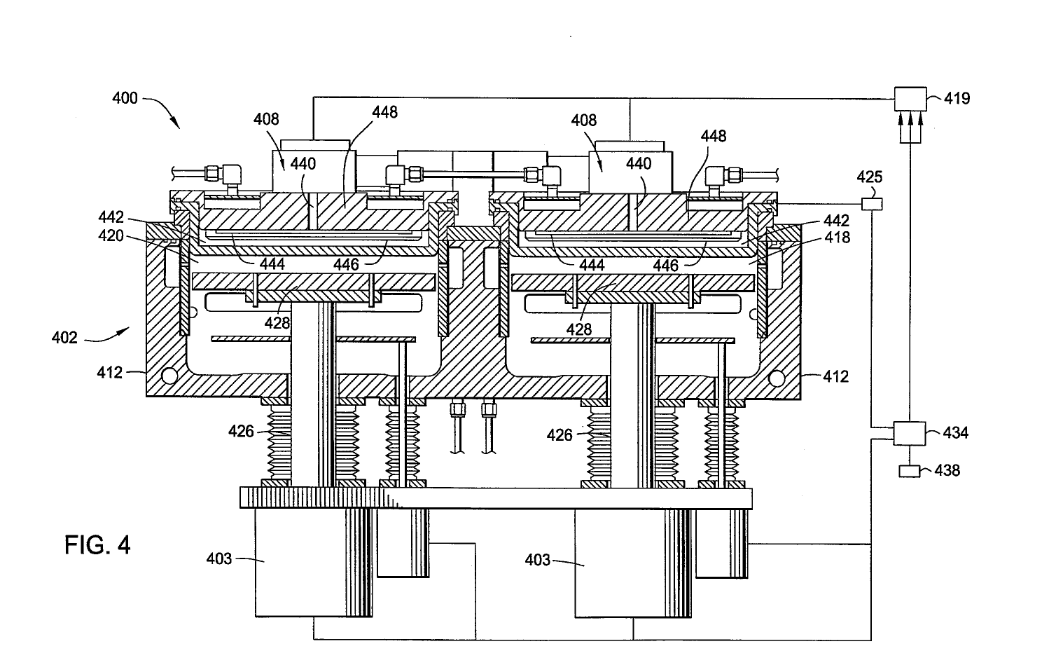

FIG. 4 is a cross sectional schematic diagram of a chemical vapor deposition chamber 400 that may be used for practicing embodiments of the invention. An example of such a chamber is a dual or twin chamber of a PRODUCER® system, available from Applied Materials, Inc. of Santa Clara, Calif. The twin chamber has two isolated processing regions (for processing two substrates, one substrate per processing region) such that the flow rates experienced in each region are approximately one half of the flow rates into the whole chamber. The flow rates described in the examples below and throughout the specification are the flow rates for processing a 300 mm substrate. A chamber having two isolated processing regions is further described in U.S. Pat. No. 5,855,681, which is incorporated by reference herein. Another example of a chamber that may be used is a DxZ® chamber on a CENTURA® system which are available from Applied Materials, Inc.

The CVD chamber 400 has a chamber body 402 that defines separate processing regions 418, 420. Each processing region 418, 420 has a pedestal 428 for supporting a substrate (not shown) within the CVD chamber 400. Each pedestal 428 typically includes a heating element (not shown). Each pedestal 428 is movably disposed in one of the processing regions 418, 420 by a stem 426 which extends through the bottom of the chamber body 402 where it is connected to a drive system 403.

Each of the processing regions 418, 420 may include a gas distribution assembly 408 disposed through a chamber lid 404 to deliver gases into the processing regions 418, 420. The gas distribution assembly 408 of each processing region normally includes a gas inlet passage 440 which delivers gas from a gas flow controller 419 into a gas distribution manifold 442, which is also known as a showerhead assembly. Gas flow controller 419 is typically used to control and regulate the flow rates of different process gases into the chamber. Other flow control components may include a liquid flow injection valve and liquid flow controller (not shown) if liquid precursors are used. The gas distribution manifold 442 comprises an annular base plate 448, a face plate 446, and a blocker plate 444 between the base plate 448 and the face plate 446. The gas distribution manifold 442 includes a plurality of nozzles (not shown) through which gaseous mixtures are injected during processing. An RF (radio frequency) source 425 provides a bias potential to the gas distribution manifold 442 to facilitate generation of a plasma between the showerhead assembly 442 and the pedestal 428. During a plasma-enhanced chemical vapor deposition process, the pedestal 428 may serve as a cathode for generating the RF bias within the chamber body 402. The cathode is electrically coupled to an electrode power supply to generate a capacitive electric field in the deposition chamber 400. Typically an RF voltage is applied to the cathode while the chamber body 402 is electrically grounded. Power applied to the pedestal 428 creates a substrate bias in the form of a negative voltage on the upper surface of the substrate. This negative voltage is used to attract ions from the plasma formed in the chamber 400 to the upper surface of the substrate.

During processing, process gases are uniformly distributed radially across the substrate surface. The plasma is formed from one or more process gases or a gas mixture by applying RF energy from the RF power supply 425 to the gas distribution manifold 442, which acts as a powered electrode. Film deposition takes place when the substrate is exposed to the plasma and the reactive gases provided therein. The chamber walls 412 are typically grounded. The RF power supply 425 can supply either a single or mixed-frequency RF signal to the gas distribution manifold 442 to enhance the decomposition of any gases introduced into the processing regions 418, 420.

A system controller 434 controls the functions of various components such as the RF power supply 425, the drive system 403, the lift mechanism 406, the gas flow controller 419, and other associated chamber and/or processing functions. The system controller 434 executes system control software stored in a memory 438, which in the preferred embodiment is a hard disk drive, and can include analog and digital input/output boards, interface boards, and stepper motor controller boards. Optical and/or magnetic sensors are generally used to move and determine the position of movable mechanical assemblies.

The above CVD system description is mainly for illustrative purposes, and other plasma processing chambers may also be employed for practicing embodiments of the invention.

### EXAMPLE

In the case a thin layer of CuSiN is directly formed on the substrate by performing a NH₃ plasma treatment on the conductive surface of the substrate, subsequently, introducing SiH₄ over a Cu surface, and followed by a NH₃ post plasma treatment. The CuSiN layer is performed as interfacial adhesion promoting and electromigration improving layer between the conductive material and the to-be-deposited barrier dielectric layer, such as a silicon carbide. After the CuSiN is formed on the substrate, the barrier dielectric layer may be deposited directly on the CuSiN with enhanced adhesion and improved electromigration while maintaining resistivity within a desired range.

While the foregoing is directed to embodiments of the present invention, other and further embodiments of the invention may be devised without departing from the basic scope thereof, and the scope thereof is determined by the claims that follow.

1. A method for processing a substrate, comprising:
providing a substrate comprising a conductive material;
performing a pre-treatment process on the conductive material;
flowing a silicon based compound on the conductive material to form a silicide layer;
performing a post treatment process on the silicide layer using NH₃ gas; and
depositing a barrier dielectric layer on the substrate.

2. The method of claim 1, wherein the conductive material comprises copper.

3. The method of claim 1, wherein the silicide layer comprises silicon nitride.

4. The method of claim 1, wherein the barrier layer comprises silicon carbide.

5. The method of claim 1, wherein performing the post treatment process includes:
performing a plasma nitridation process to the surface of the silicide layer.

6. The method of claim 5, wherein performing the post treatment process includes:
forming a metal nitrosilicide layer on the substrate.

7. The method of claim 5, wherein the nitrosilicide layer is a copper silicon nitride layer.

8. The method of claim 7, wherein the copper silicon nitride layer is between about 1 Å and about 100 Å thick.

9. The method of claim 7, wherein copper silicon nitride layer is between about 1 Å and about 50 Å thick.

10. (canceled)

11. A method for processing a substrate, comprising:
providing a substrate comprising a conductive material;
flowing a silicon based compound over the surface of the conductive material to form a silicide;
treating the substrate with NH₃ gas containing plasma to form a metal nitrosilicide layer; and
depositing a barrier layer on the substrate.

12. The method of claim 11, wherein the conductive material comprises copper.

13. The method of claim 11, wherein the silicide layer comprises silicon nitride.

14. The method of claim 11, wherein the barrier layer comprises silicon carbide.

15. The method of claim 11, wherein the metal nitrosilicide layer comprises copper silicon nitride.

16. The method of claim 15, wherein the metal nitrosilicide layer is between about 1 Å and about 100 Å thick.

17. The method of claim 15, wherein the metal nitrosilicide layer is between about 1 Å and about 50 Å thick.

18. The method of claim 11, wherein the NH₃ gas containing plasma is formed by applying RF power gas.

19. The method of claim 11, wherein treating the substrate comprises maintaining the RF power utilized to maintain the NH₃ gas containing plasma while depositing the metal nitrosilicide layer on the substrate.

20. A method for processing a substrate, comprising:
providing a substrate comprising a conductive material;
performing a nitrogen pre-treatment process by a NH₃ gas on the conductive material;
flowing a silane gas over the surface of the conductive material to form a silicide;
treating the silicide with a NH₃ gas containing plasma to form a metal nitrosilicide; and
depositing a barrier dielectric layer comprising silicon carbide on the nitrosilicide.
